(19) United States
(12) Patent Application Publication
(10) Pub. No.: US 2025/0057027 A1
(43) Pub. Date: Feb. 13, 2025

(54) MANUFACTURING METHOD OF DISPLAY DEVICE

(71) Applicant: Japan Display Inc., Tokyo (JP)

(72) Inventors: Arichika ISHIDA, Tokyo (JP); Kaichi FUKUDA, Tokyo (JP)

(73) Assignee: Japan Display Inc., Tokyo (JP)

(21) Appl. No.: 18/788,234

(22) Filed: Jul. 30, 2024

(30) Foreign Application Priority Data
Aug. 9, 2023 (JP) 2023-130141

(51) Int. Cl. H10K 71/16; H10K 59/12

(52) U.S. Cl. CPC H10K 71/166; H10K 59/1201

(57) ABSTRACT

According to one embodiment, a manufacturing method of a display device includes forming a lower electrode, an inorganic insulating layer, a lower portion layer and an upper portion layer in series, removing the upper and lower portion layers exposed from a first resist in series, forming an aperture which overlaps the lower electrode in the inorganic insulating layer, forming a partition which has a lower portion located on the inorganic insulating layer and an upper portion located on the lower portion and protruding from a side surface of the lower portion, and forming a stacked film including an organic layer and an upper electrode on the lower electrode in the aperture by performing vapor deposition using the partition as a mask.

### CROSS-REFERENCE TO RELATED APPLICATIONS

This application is based upon and claims the benefit of priority from Japanese Patent Application No. 2023-130141, filed Aug. 9, 2023, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer.

In the process of manufacturing such a display element, a technique which prevents the reduction in reliability has been required.

### BRIEF DESCRIPTION OF THE DRAWINGS

FIG. 1 is a plan view showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4A is a diagram for explaining a manufacturing method of the display device.

FIG. 4B is a diagram for explaining the manufacturing method of the display device.

FIG. 4C is a diagram for explaining the manufacturing method of the display device.

FIG. 4D is a diagram for explaining the manufacturing method of the display device.

FIG. 4E is a diagram for explaining the manufacturing method of the display device.

FIG. 4F is a diagram for explaining the manufacturing method of the display device.

FIG. 4G is a diagram for explaining the manufacturing method of the display device.

FIG. 4H is a diagram for explaining the manufacturing method of the display device.

FIG. 4I is a diagram for explaining the manufacturing method of the display device.

FIG. 5 is a diagram for explaining the manufacturing method of the display device.

FIG. 6 is a diagram for explaining the manufacturing method of the display device.

FIG. 7 is a diagram for explaining the manufacturing method of the display device.

FIG. 8 is a diagram for explaining the manufacturing method of the display device.

FIG. 9 is a diagram for explaining the manufacturing method of the display device.

FIG. 10 is a diagram for explaining the manufacturing method of the display device.

FIG. 11A is a diagram for explaining another manufacturing method.

FIG. 11B is a diagram for explaining another manufacturing method.

FIG. 12A is a diagram for explaining another manufacturing method.

FIG. 12B is a diagram for explaining another manufacturing method.

FIG. 12C is a diagram for explaining another manufacturing method.

FIG. 13 is a cross-sectional view showing the display elements DE1, DE2 and DE3 formed through the manufacturing method shown in FIG. 12A to FIG. 12C.

FIG. 14 is a cross-sectional view in which the display elements DE1 and DE2 shown in FIG. 13 are enlarged.

### DETAILED DESCRIPTION

Embodiments described herein aim to provide a display device and a manufacturing method thereof such that the reduction in reliability can be prevented.

In general, according to one embodiment, a manufacturing method of a display device comprises forming a lower electrode above a substrate, forming an inorganic insulating layer which covers the lower electrode, forming a lower portion layer and an upper portion layer on the inorganic insulating layer in series, forming a patterned first resist on the upper portion layer, removing the upper and lower portion layers exposed from the first resist in series by performing etching using the first resist as a mask, forming a second resist which covers the lower portion layer and the upper portion layer and from which the inorganic insulating layer is exposed after removing the first resist, forming an aperture which overlaps the lower electrode in the inorganic insulating layer by performing etching using the second resist as a mask, forming a partition which has a lower portion located on the inorganic insulating layer and an upper portion located on the lower portion and protruding from a side surface of the lower portion by applying etching to the lower portion layer, after removing the second resist, and forming a stacked film including an organic layer and an upper electrode on the lower electrode in the aperture by performing vapor deposition using the partition as a mask.

According to another embodiment, a manufacturing method of a display device comprises forming a lower electrode above a substrate, forming an inorganic insulating layer which covers the lower electrode, forming a lower portion layer and an upper portion layer on the inorganic insulating layer in series, forming a patterned first resist on the upper portion layer, forming an aperture which overlaps the lower electrode in the inorganic insulating layer by performing etching using the first resist as a mask such that the upper portion layer, the lower portion layer and the inorganic insulating layer exposed from the first resist are removed in series, forming a partition which has a lower portion located on the inorganic insulating layer and an upper portion located on the lower portion and protruding from a side surface of the lower portion by applying etching to the lower portion layer, after removing the first resist, and forming a stacked film including an organic layer and an upper electrode on the lower electrode in the aperture by performing vapor deposition using the partition as a mask.

The embodiments can provide a display device and a manufacturing method thereof such that the reduction in reliability can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and may be mounted on a television, a personal computer, a vehicle-mounted device, a tablet, a smartphone, a mobile phone, etc.

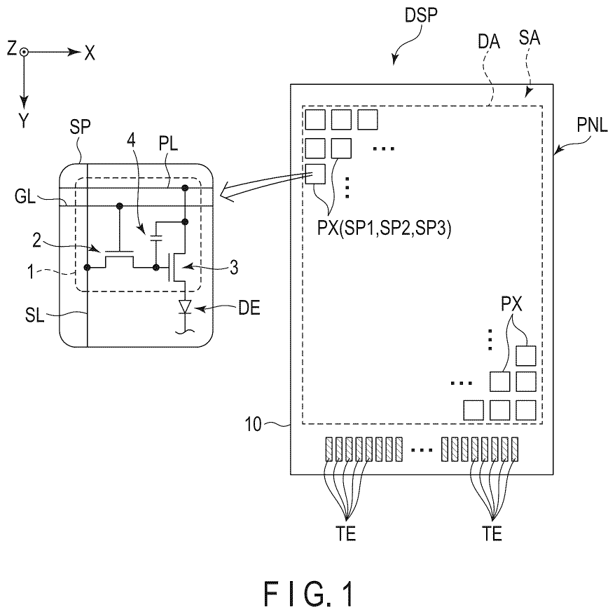

FIG. 1 is a plan view showing a configuration example of a display device DSP.

The display device DSP comprises a display panel PNL having a display area DA which displays an image and a surrounding area SA located on an external side relative to the display area DA on an insulating substrate 10. The substrate 10 may be either a glass substrate or a resinous substrate having flexibility.

In the embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element DE.

It should be noted that the configuration of the pixel circuit 1 is not limited to the example shown in the figure. For example, the pixel circuit 1 may comprise more thin-film transistors and capacitors.

The display element DE is an organic light emitting diode (OLED) as a light emitting element, and may be called an organic EL element.

The surrounding area SA comprises a plurality of terminals TE which are arranged along one direction. In the example shown in the figure, the terminals TE are arranged in the first direction X. Although all of the terminals TE extend in the second direction Y, the configuration is not limited to this example. For example, some of the terminals TE may extend in an oblique direction. For example, these terminals TE are electrically connected to a flexible printed circuit and an IC chip.

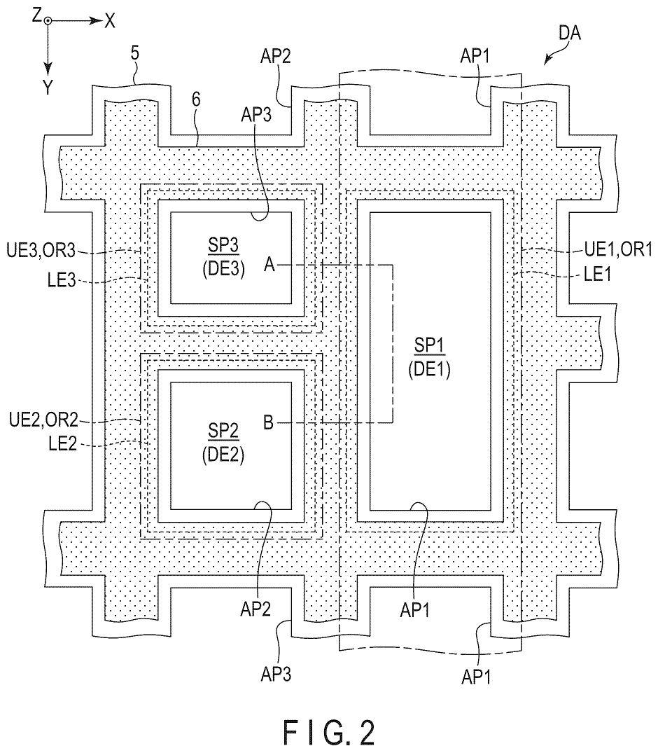

FIG. 2 is a diagram showing an example of the layout of subpixels SP1, SP2 and SP3.

In the example shown in the figure, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An insulating layer 5 and a partition 6 are provided in the display area DA. The insulating layer 5 has apertures AP1, AP2 and AP3 in subpixels SP1, SP2 and SP3, respectively. The insulating layer 5 having these apertures AP1, AP2 and AP3 may be called a rib.

The partition 6 overlaps the insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the insulating layer 5. The partition 6 is conductive and is electrically connected to, of the terminals TE shown in FIG. 1, each terminal TE having a common potential.

Subpixels SP1, SP2 and SP3 comprise display elements DE1, DE2 and DE3, respectively, as the display elements DE.

The display element DE1 of subpixel SP1 comprises a lower electrode LE1, an upper electrode UE1 and an organic layer OR1 overlapping the aperture AP1. The lower electrode LE1, the organic layer OR1 and the upper electrode UE1 are surrounded by the partition 6 in plan view. The peripheral portion of each of the lower electrode LE1, the organic layer OR1 and the upper electrode UE1 overlaps the insulating layer 5 in plan view.

The display element DE2 of subpixel SP2 comprises a lower electrode LE2, an upper electrode UE2 and an organic layer OR2 overlapping the aperture AP2. The lower electrode LE2, the organic layer OR2 and the upper electrode UE2 are surrounded by the partition 6 in plan view. The peripheral portion of each of the lower electrode LE2, the organic layer OR2 and the upper electrode UE2 overlaps the insulating layer 5 in plan view.

The display element DE3 of subpixel SP3 comprises a lower electrode LE3, an upper electrode UE3 and an organic layer OR3 overlapping the aperture AP3. The lower electrode LE3, the organic layer OR3 and the upper electrode UE3 are surrounded by the partition 6 in plan view. The peripheral portion of each of the lower electrode LE3, the organic layer OR3 and the upper electrode UE3 overlaps the insulating layer 5 in plan view.

In the example shown in the figure, the outer shapes of the lower electrodes LE1, LE2 and LE3 are shown by broken lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode and are in contact with the partition 6.

In the example shown in the figure, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

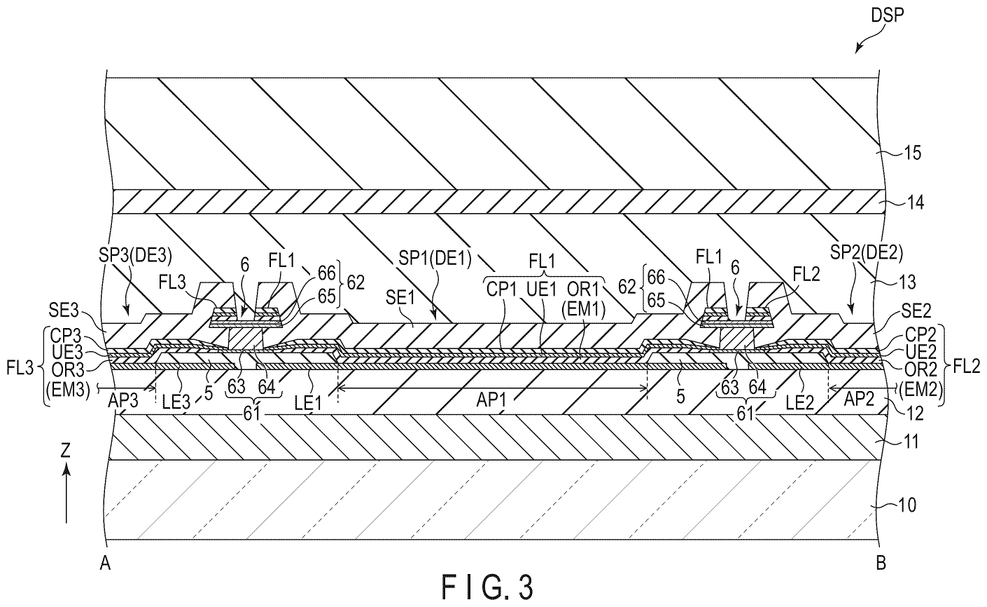

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The insulating layer 5 is an inorganic insulating layer and is provided on the insulating layer 12 and the lower electrodes LE1, LE2 and LE3. The aperture AP1 of the insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the insulating layer 5. The lower electrodes LE1, LE2 and LE3 are connected to the pixel circuits 1 of subpixels SP1, SP2 and SP3, respectively, through contact holes provided in the insulating layer 12. It should be noted that the contact holes of the insulating layer 12 are omitted in FIG. 3.

The partition 6 includes a conductive lower portion 61 provided on the insulating layer 5 and an upper portion 62 provided on the lower portion 61. The upper portion 62 has a width greater than that of the lower portion 61. The both end portions of the upper portion 62 protrude relative to the side surfaces of the lower portion 61. This shape of the partition 6 is called an overhang shape.

In the example shown in the figure, the lower portion 61 has a first conductive layer 63 provided on the insulating layer 5 and a second conductive layer 64 provided on the first conductive layer 63. For example, the first conductive layer 63 is formed so as to be thinner than the second conductive layer 64. In the example shown in the figure, the both end portions of the first conductive layer 63 protrude from the side surfaces of the second conductive layer 64.

The upper portion 62 has a first thin film 65 provided on the second conductive layer 64 and a second thin film 66 provided on the first thin film 65. The both end portions of the first thin film 65 and the second thin film 66 protrude from the side surfaces of the second conductive layer 64.

The organic layer OR1 is in contact with the lower electrode LE1 through the aperture AP1 and covers the lower electrode LE1 exposed from the aperture AP1. The peripheral portion of the organic layer OR1 is located on the insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the insulating layer 5. The upper electrode UE3 covers the organic layer OR3 and is in contact with the lower portion 61.

In the example shown in the figure, subpixel SP1 has a cap layer CP1 and a sealing layer SE1. Subpixel SP2 has a cap layer CP2 and a sealing layer SE2. Subpixel SP3 has a cap layer CP3 and a sealing layer SE3. The cap layers CP1, CP2 and CP3 function as optical adjustment layers which improve the extraction efficiency of the light emitted from the organic layers OR1, OR2 and OR3, respectively. It should be noted that the cap layers CP1, CP2 and CP3 may be omitted.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

In the example shown in the figure, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element DE1).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element DE2).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element DE3).

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The end portions of the sealing layers SE1, SE2 and SE3 and the end portions of the stacked films FL1, FL2 and FL3 are located on the partition 6. In the example shown in the figure, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The sealing layers SE1, SE2 and SE3 are covered with a resin layer 13. The resin layer 13 is covered with a sealing layer 14. The sealing layer 14 is covered with a resin layer 15.

Each of the insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. The first conductive layer 63 is formed of, for example, a titanium-based material such as titanium or a titanium compound. The second conductive layer 64 is formed of a material which is different from the first conductive layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The first thin film 65 is formed of, for example, a titanium-based material such as titanium or a titanium compound. The second thin film 66 is formed of, for example, an oxide conductive material such as indium tin oxide (ITO).

Each of the lower electrodes LE1, LE2 and LE3 is a multilayer body including a transparent layer formed of an oxide conductive material such as indium tin oxide (ITO) and a reflective layer formed of a metal material such as silver. For example, each of the lower electrodes LE1, LE2 and LE3 is a multilayer body including a reflective layer between a pair of transparent layers. The lower transparent layer functions as an adhesive layer which adheres tightly to the insulating layer 12.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, insulating layer 12, insulating layer 5, resin layer 13, resin layer 15 and sealing layer 14 shown in the figure are provided over the display area DA and the surrounding area SA.

Now, this specification explains a manufacturing method of the display device DSP. Regarding each figure for explaining the manufacturing method, the illustration of the lower side of the insulating layer 12 is omitted.

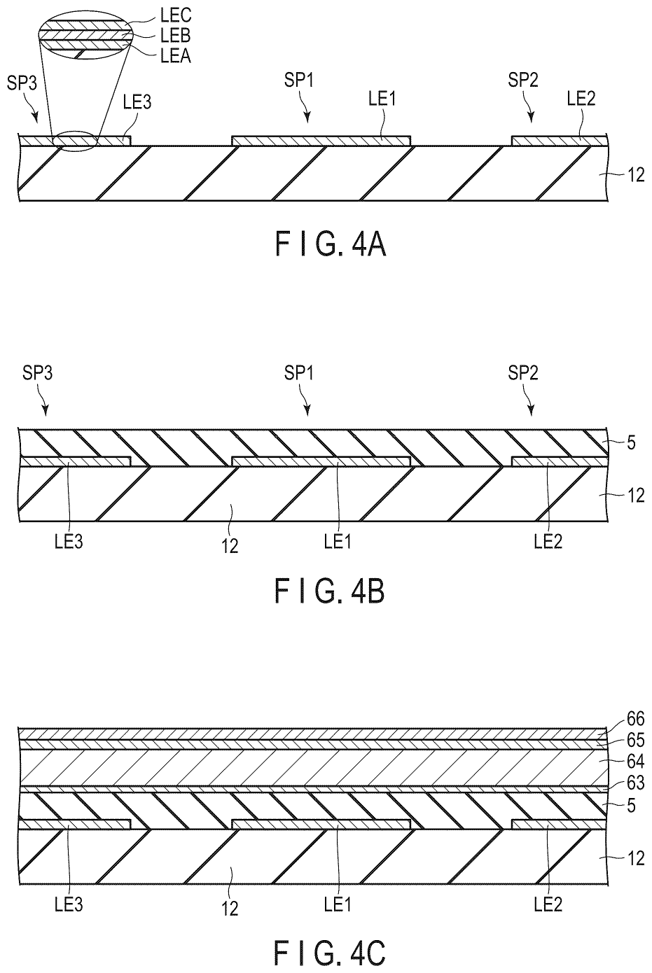

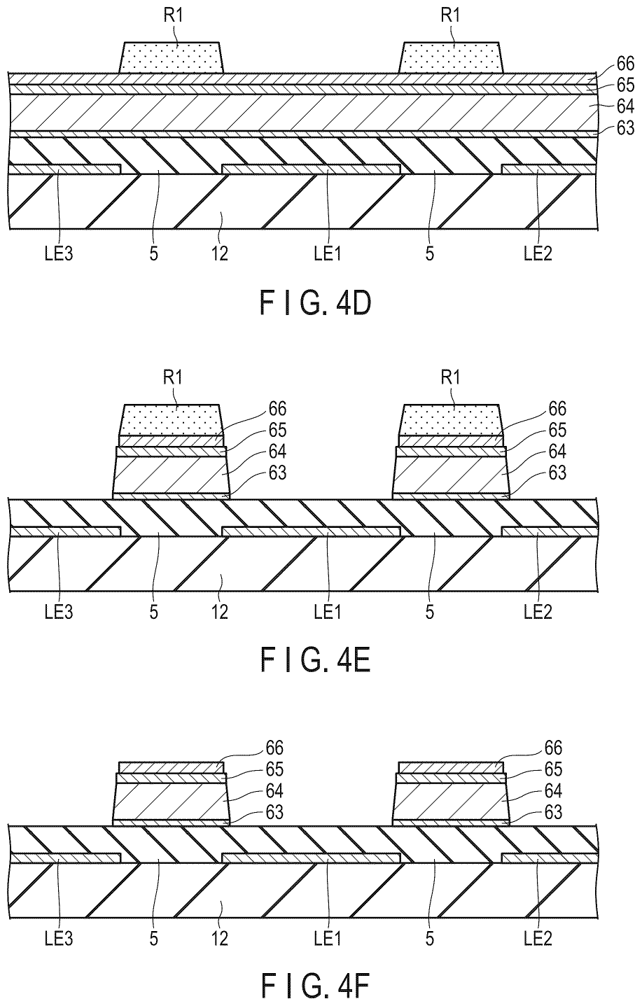

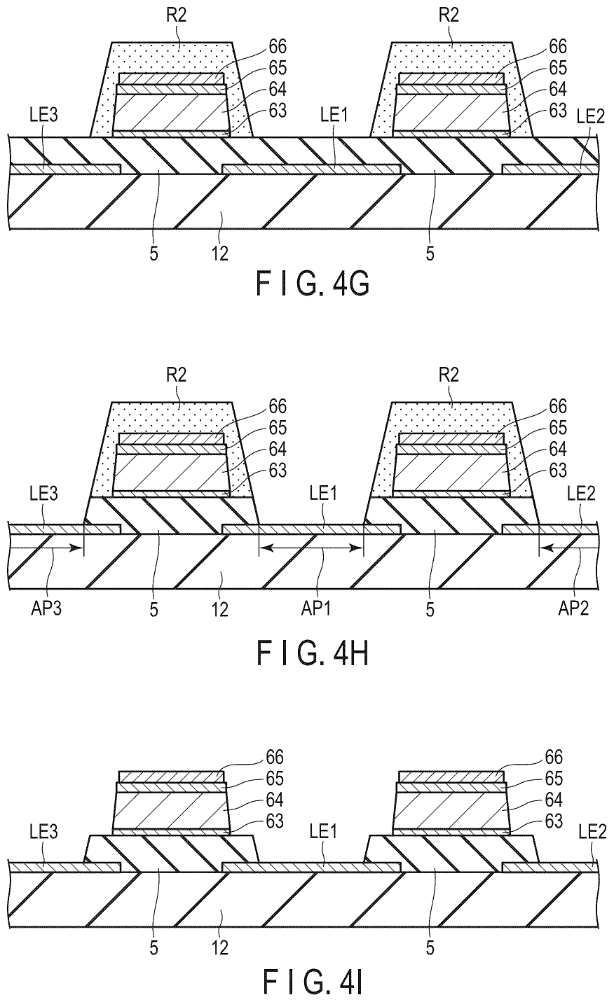

First, the circuit layer 11 and the insulating layer 12 are formed on the substrate 10 over the display area DA and the surrounding area SA. Subsequently, as shown in FIG. 4A, the lower electrode LE1 of subpixel SP1, the lower electrode LE2 of subpixel SP2 and the lower electrode LE3 of subpixel SP3 are formed on the insulating layer 12. The process of forming the lower electrodes LE1, LE2 and LE3 includes, for example, the following processes. The process of forming each lower electrode includes the process of forming an adhesive layer LEA on the insulating layer 12, the process of forming a reflective layer LEB on the adhesive layer LEA, the process of forming a transparent layer LEC on the reflective layer LEB and the process of patterning the adhesive layer LEA, the reflective layer LEB and the transparent layer LEC. By this process, the multilayer body consisting of the adhesive layer LEA, the reflective layer LEB and the transparent layer LEC is formed into an island-like shape. These multilayer bodies correspond to the lower electrodes LE1, LE2 and LE3, respectively. The adhesive layer LEA is formed of, for example, ITO. The reflective layer LEB is formed of, for example, silver. The transparent layer LEC is formed of, for example, ITO.

Subsequently, as shown in FIG. 4B, the insulating layer 5 which covers the insulating layer 12 and the lower electrodes LE1, LE2 and LE3 is formed by depositing an inorganic insulating material such as silicon oxide, silicon nitride or silicon oxynitride.

Subsequently, as shown in FIG. 4C, a lower portion layer for forming the lower portion 61 of the partition 6 is formed on the insulating layer 5, and subsequently, an upper portion layer for forming the upper portion 62 of the partition 6 is formed on the lower portion layer.

The process of forming the lower portion layer includes the process of forming the first conductive layer 63 on the insulating layer 5 by using a titanium-based material, and the process of forming the second conductive layer 64 on the first conductive layer 63 by using an aluminum-based material. Thus, the lower portion layer is a multilayer body consisting of the first conductive layer 63 and the second conductive layer 64.

The process of forming the upper portion layer includes the process of forming the first thin film 65 on the second conductive layer 64 by using a titanium-based material, and the process of forming the second thin film 66 on the first thin film 65 by using ITO. Thus, the upper portion layer is a multilayer body consisting of the first thin film 65 and the second thin film 66.

Subsequently, as shown in FIG. 4D, a first resist R1 patterned into a predetermined shape is formed on the second thin film 66 of the upper portion layer.

Subsequently, as shown in FIG. 4E, the upper portion layer exposed from the first resist R1 is removed by performing etching using the first resist R1 as a mask, and subsequently, the lower portion layer is removed. Specifically, first, the second thin film 66 is removed by wet etching. Subsequently, the first thin film 65 is removed by dry etching. Subsequently, the second conductive layer 64 is removed. Further, the first conductive layer 63 is removed. Thus, the insulating layer 5 is exposed immediately above the lower electrodes LE1, LE2 and LE3.

Subsequently, as shown in FIG. 4F, the first resist R1 is removed.

Subsequently, as shown in FIG. 4G, a second resist R2 which covers the first and second conductive layers 63 and 64 as the lower portion layer and the first and second thin films 65 and 66 as the upper portion layer is formed. The second resist R2 covers the upper surface of the second thin film 66 and also covers the side surfaces of the lower portion layer and the upper portion layer. The second resist R2 is in contact with the insulating layer 5 around the first conductive layer 63. The insulating layer 5 is exposed from the second resist R2 immediately above the lower electrodes LE1, LE2 and LE3.

Subsequently, as shown in FIG. 4H, etching is performed using the second resist R2 as a mask. Specifically, the insulating layer 5 exposed from the second resist R2 is removed by dry etching to form the apertures AP1, AP2 and AP3. The aperture AP1 overlaps the lower electrode LE1 of subpixel SP1. The aperture AP2 overlaps the lower electrode LE2 of subpixel SP2. The aperture AP3 overlaps the lower electrode LE3 of subpixel SP3.

Subsequently, as shown in FIG. 4I, the second resist R2 is removed.

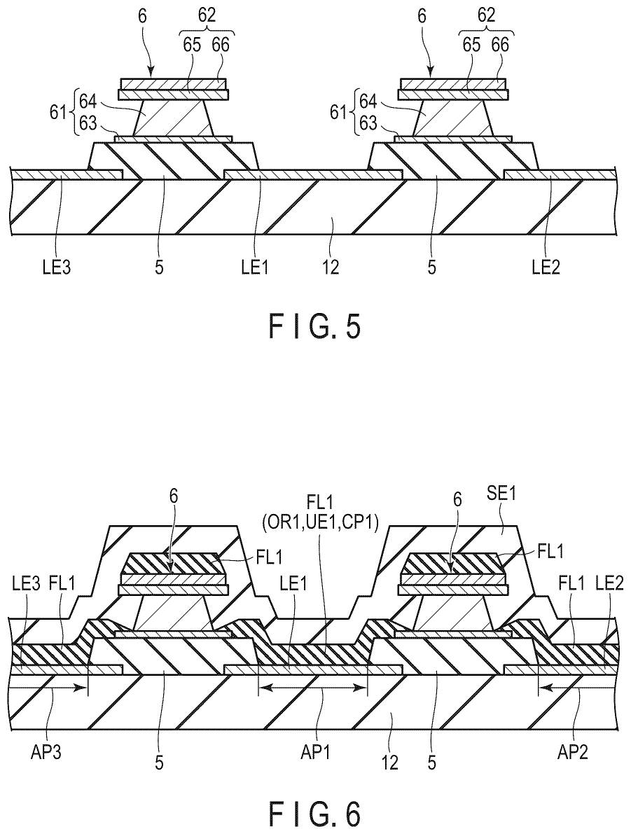

Subsequently, as shown in FIG. 5, the second conductive layer 64 of the lower portion layer is etched. Specifically, the second conductive layer 64 is retracted from the end portion of each of the first conductive layer 63 and the upper portion layer by wet etching. This process allows the formation of the partition 6 which has the lower portion 61 located on the insulating layer 5 and the upper portion 62 located on the lower portion 61 and protruding from the side surfaces of the second conductive layer 64.

Subsequently, the display element DE1 is formed.

First, as shown in FIG. 6, the stacked film FL1 including the organic layer OR1, the upper electrode UE1 and the cap layer CP1 is formed. The process of forming the stacked film FL1 includes the process of forming the organic layer OR1 which is in contact with the lower electrode LE1 in the aperture AP1, the process of forming the upper electrode UE1 which covers the organic layer OR1 and is in contact with the lower portion 61 of the partition 6, and the process of forming the cap layer CP1 located on the upper electrode UE1. The organic layer OR1 includes a hole injection layer, a hole transport layer, an electron blocking layer, the light emitting layer EM1, a hole blocking layer, an electron transport layer, an electron injection layer and the like. Each of the organic layer OR1, the upper electrode UE1 and the cap layer CP1 is formed by vapor deposition using the partition 6 as a mask. The stacked film FL1 is divided into a plurality of portions by the partition 6 having an overhang shape. These organic layer OR1, upper electrode UE1 and cap layer CP1 are continuously formed while maintaining a vacuum environment.

Subsequently, the sealing layer SE1 is formed on the stacked film FL1 by depositing an inorganic insulating material. The sealing layer SE1 is formed by chemical vapor deposition (CVD). The sealing layer SE1 continuously covers the portions into which the stacked film FL1 is divided, and the partition 6.

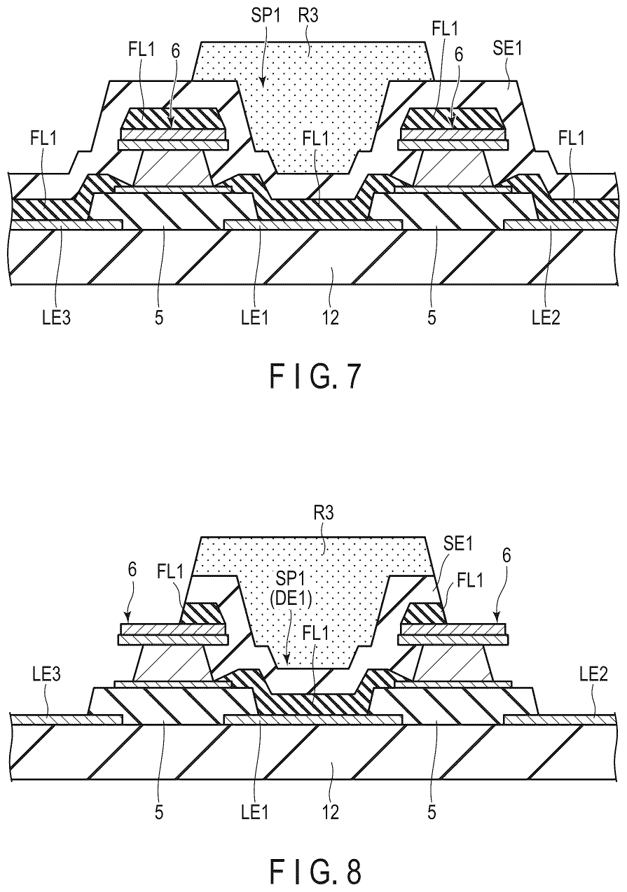

Subsequently, as shown in FIG. 7, a third resist R3 patterned into a predetermined shape is formed on the sealing layer SE1. The third resist R3 overlaps subpixel SP1 and part of the partition 6 around subpixel SP1.

Subsequently, as shown in FIG. 8, the sealing layer SE1 and the stacked film FL1 exposed from the third resist R3 are removed by performing etching using the third resist R3 as a mask. In this etching, the sealing layer SE1 exposed from the third resist R3 is removed. Subsequently, the cap layer CP1 exposed from the sealing layer SE1 is removed. Further, the upper electrode UE1 exposed from the cap layer CP1 is removed. Subsequently, the organic layer OR1 exposed from the upper electrode UE1 is removed. In this manner, the lower electrode LE2 of subpixel SP2 and the lower electrode LE3 of subpixel SP3 are exposed.

Subsequently, the third resist R3 is removed. By this process, the display element DE1 is formed in subpixel SP1.

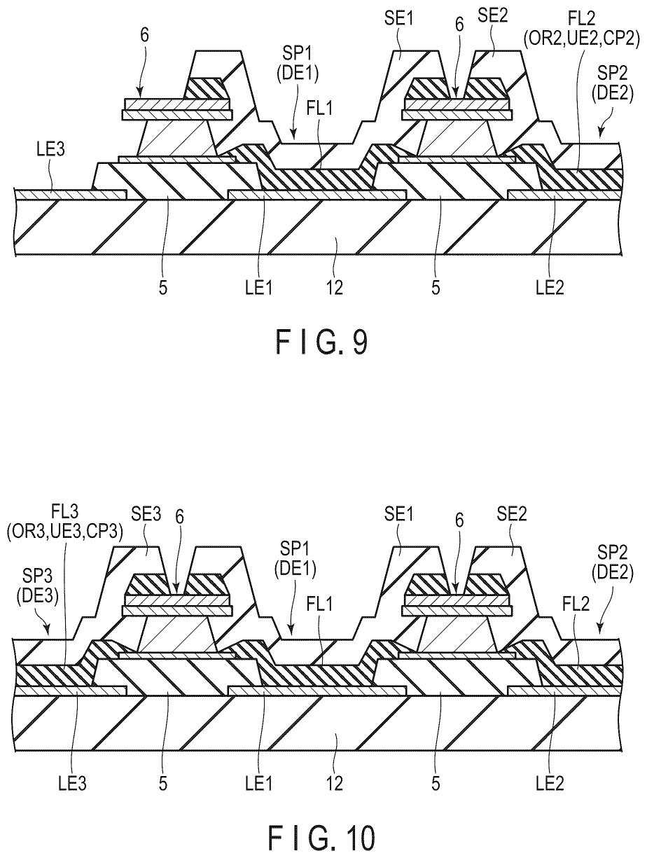

Subsequently, the display element DE2 is formed as shown in FIG. 9. The procedure of forming the display element DE2 is similar to that of forming the display element DE1. Specifically, the stacked film FL2 is formed by forming the organic layer OR2 including the light emitting layer EM2, the upper electrode UE2 and the cap layer CP2 in order on the lower electrode LE2. Subsequently, the sealing layer SE2 is formed on the stacked film FL2. Subsequently, a resist is formed on the sealing layer SE2. The sealing layer SE2, the cap layer CP2, the upper electrode UE2 and the organic layer OR2 are patterned by etching using the resist as a mask. After this patterning, the resist is removed. In this manner, the display element DE2 is formed in subpixel SP2, and the lower electrode LE3 of subpixel SP3 is exposed.

Subsequently, the display element DE3 is formed as shown in FIG. 10. The procedure of forming the display element DE3 is similar to that of forming the display element DE1. Specifically, the stacked film FL3 is formed by forming the organic layer OR3 including the light emitting layer EM3, the upper electrode UE3 and the cap layer CP3 in order on the lower electrode LE3. Subsequently, the sealing layer SE3 is formed on the stacked film FL3. Subsequently, a resist is formed on the sealing layer SE3. The sealing layer SE3, the cap layer CP3, the upper electrode UE3 and the organic layer OR3 are patterned by etching using the resist as a mask. After this patterning, the resist is removed. By this process, the display element DE3 is formed in subpixel SP3.

Subsequently, the resin layer 13, sealing layer 14 and resin layer 15 shown in FIG. 3 and the like are formed in order. By this process, the display device DSP is completed.

In the manufacturing process described above, this specification assumes a case where the display element DE1 is formed firstly, and the display element DE2 is formed secondly, and the display element DE3 is formed lastly. However, the formation order of the display elements DE1, DE2 and DE3 is not limited to this example.

Here, as comparative example 1, this specification explains a case where the apertures AP1, AP2 and AP3 are formed in the insulating layer 5 before the partition 6 is formed.

In this comparative example 1, the first conductive layer is formed on the lower electrodes LE1, LE2 and LE3 exposed from the apertures AP1, AP2 and AP3, respectively, by sputtering. When the partition 6 is formed, dry etching is applied to the first conductive layer. The transparent layers of the surfaces of the lower electrodes LE1, LE2 and LE3 may be damaged by these sputtering and dry etching.

To the contrary, in the manufacturing method of the embodiment, the sputtering and dry etching processes of the first conductive layer are performed before the apertures AP1, AP2 and AP3 are formed. Thus, the damage to the lower electrodes LE1, LE2 and LE3 is prevented. In this manner, the desired display performance can be realized in each of the display elements DE1, DE2 and DE3, thereby preventing the reduction in reliability.

Now, as comparative example 2, this specification explains a case where the apertures AP1, AP2 and AP3 are formed in the insulating layer 5 by covering the partition 6 with a resist after the formation of the partition 6.

In this comparative example 2, when the partition 6 having an overhang shape is covered with a resist, a cavity is easily generated in the resist under the upper portion 62 to be eaves. This cavity may expand and burst when the resist is dried under reduced pressure. In this case, the necessary resist may be partly lost, and a pattern defect may occur. Thus, there is a possibility that the formation of the desired apertures AP1, AP2 and AP3 in the insulating layer 5 is difficult. In addition, when the application speed of the resist is reduced to prevent the generation of a cavity, the productivity may be decreased.

To the contrary, in the manufacturing method of the embodiment, as explained with reference to FIG. 4G, the multilayer body of the first conductive layer 63, the second conductive layer 64, the first thin film 65 and the second thin film 66 is covered with the second resist R2 before the formation of the partition 6 having an overhang shape. This configuration prevents the generation of a cavity in the second resist R2 without decreasing the application speed of the resist. In this manner, the desired apertures AP1, AP2 and AP3 can be formed in the insulating layer 5 without decreasing the productivity.

Now, this specification explains another manufacturing method of the display device DSP.

First, the lower electrodes LE1, LE2 and LE3 are formed in a manner similar to that of the manufacturing method described above (FIG. 4A). Subsequently, the insulating layer 5 is formed (FIG. 4B). Subsequently, the first conductive layer 63, the second conductive layer 64, the first thin film 65 and the second thin film 66 are formed (FIG. 4C). Subsequently, the first resist R1 is formed (FIG. 4D). Subsequently, the first conductive layer 63, the second conductive layer 64, the first thin film 65 and the second thin film 66 are patterned (FIG. 4E). Subsequently, the first resist R1 is removed (FIG. 4F). Subsequently, the second resist R2 is formed (FIG. 4G). Subsequently, the apertures AP1, AP2 and AP3 are formed in the insulating layer 5 (FIG. 4H). Subsequently, the second resist R2 is removed (FIG. 4I).

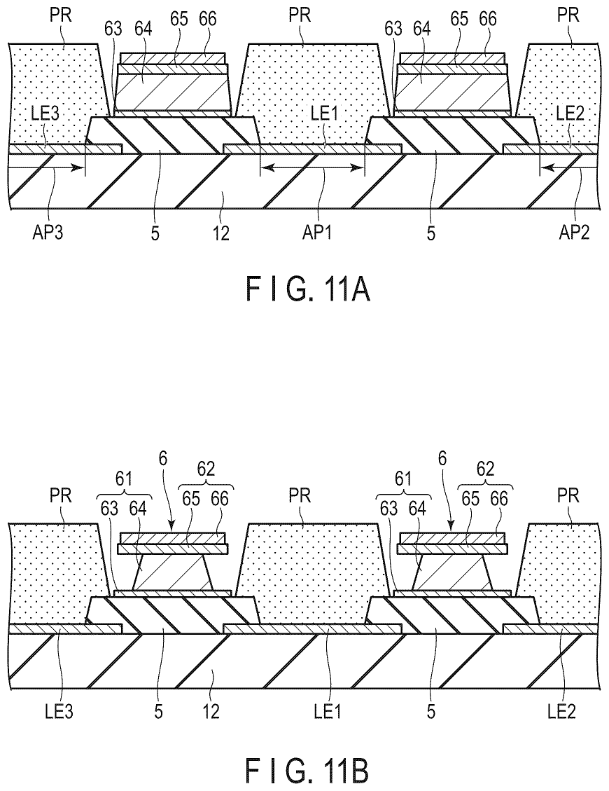

Subsequently, a protective film PR which covers each of the apertures AP1, AP2 and AP3 is formed as shown in FIG. 11A. Thus, the protective film PR covers the lower electrodes LE1, LE2 and LE3. The protective film PR may be formed of a common resist material or may be formed of resin such as polyimide.

Subsequently, the second conductive layer 64 of the lower portion layer is etched as shown in FIG. 11B. Specifically, the second conductive layer 64 is retracted from the end portion of each of the first conductive layer 63 and the upper portion layer by wet etching. This process allows the formation of the partition 6 which has the lower portion 61 located on the insulating layer 5 and the upper portion 62 located on the lower portion 61 and protruding from the side surfaces of the second conductive layer 64.

Subsequently, the protective film PR is removed.

Subsequently, in a manner similar to that of the manufacturing method descried above, the display element DE1 is formed (FIG. 6 to FIG. 8), and the display element DE2 is formed (FIG. 9), and the display element DE3 is formed (FIG. 10).

In this manufacturing method, effects similar to those of the manufacturing method described above are obtained. In addition, this manufacturing method can prevent the damage to the lower electrodes LE1, LE2 and LE3 by the etchant used at the time of the wet etching of the second conductive layer 64. For example, when a defect is generated in the transparent layers of the lower electrodes LE1, LE2 and LE3, the defect may become an incursion path of the etchant, and thus, the silver reflective layers may be corroded. For this reason, even if a defect is generated in the transparent layers, the incursion of the etchant into the reflective layers can be prevented by covering the lower electrodes LE1, LE2 and LE3 with the protective film PR before the wet etching of the second conductive layer 64. Thus, the corrosion of the reflective layers is prevented.

Now, this specification explains another manufacturing method of the display device DSP.

First, the lower electrodes LE1, LE2 and LE3 are formed in a manner similar to that of the manufacturing method described above (FIG. 4A). Subsequently, the insulating layer 5 is formed (FIG. 4B). Subsequently, the first conductive layer 63, the second conductive layer 64, the first thin film 65 and the second thin film 66 are formed (FIG. 4C). Subsequently, the first resist R1 is formed (FIG. 4D).

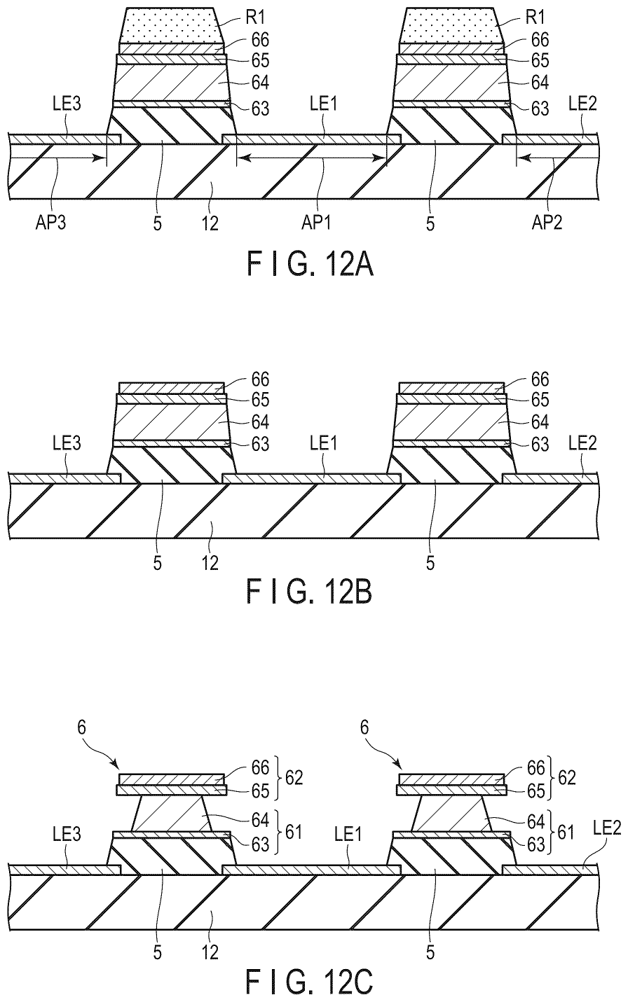

Subsequently, as shown in FIG. 12A, the upper portion layer exposed from the first resist R1 is removed by performing etching using the first resist R1 as a mask, and subsequently, the lower portion layer is removed. Further, the insulating layer 5 is removed. By this process, the apertures AP1, AP2 and AP3 are formed in the insulating layer 5. The aperture AP1 overlaps the lower electrode LE1 of subpixel SP1. The aperture AP2 overlaps the lower electrode LE2 of subpixel SP2. The aperture AP3 overlaps the lower electrode LE3 of subpixel SP3.

Specifically, first, the second thin film 66 is removed by wet etching. Subsequently, the first thin film 65 is removed by dry etching. Subsequently, the second conductive layer 64 is removed. Further, after the first conductive layer 63 is removed, the insulating layer 5 is removed.

Subsequently, as shown in FIG. 12B, the first resist R1 is removed.

Subsequently, the second conductive layer 64 of the lower portion layer is etched as shown in FIG. 12C. Specifically, the second conductive layer 64 is retracted from the end portion of each of the first conductive layer 63 and the upper portion layer by wet etching. This process allows the formation of the partition 6 which has the lower portion 61 located on the insulating layer 5 and the upper portion 62 located on the lower portion 61 and protruding from the side surfaces of the second conductive layer 64.

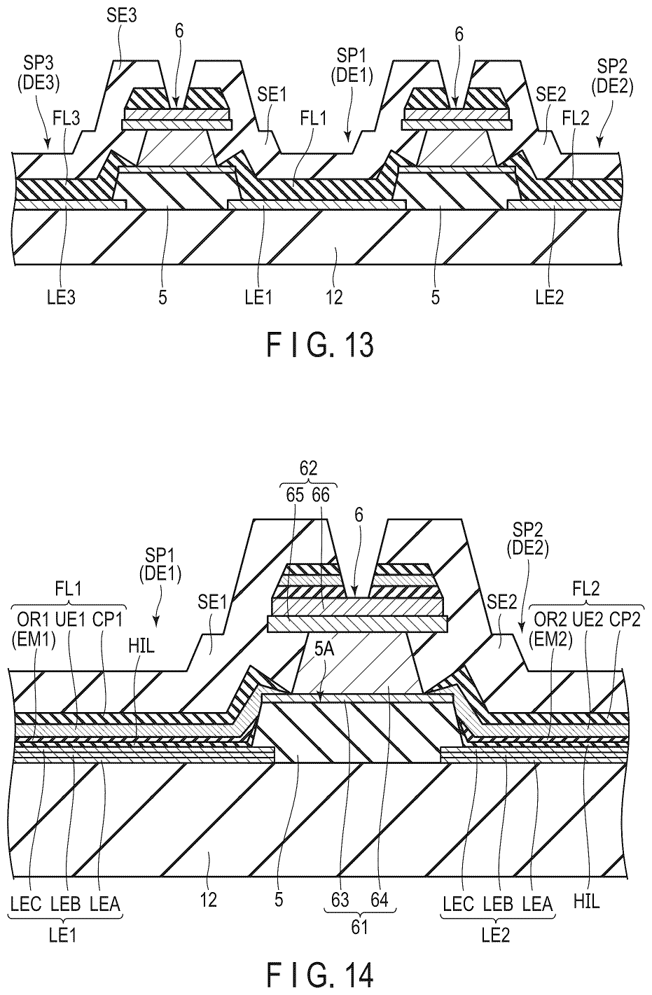

Subsequently, in a manner similar to that of the manufacturing method descried above, the display element DE1 is formed (FIG. 6 to FIG. 8), and the display element DE2 is formed (FIG. 9), and the display element DE3 is formed (FIG. 10). The display elements DE1, DE2 and DE3 formed through this process are shown in FIG. 13.

In this manufacturing method, effects similar to those of the manufacturing method described above are obtained. In addition, compared to the manufacturing method described above, the second resist is unnecessary. This configuration allows the reduction in the manufacturing cost and the simplification of the manufacturing process. Further, there is no need to consider the positional gap when the second resist is formed. Thus, the widths of the insulating layer 5 and the partition 6 can be reduced, or the apertures AP1, AP2 and AP3 (the light emitting area) can be enlarged.

It should be noted that, in the manufacturing method explained here, similarly, the lower electrodes LE1, LE2 and LE3 exposed from the apertures AP1, AP2 and AP3, respectively, may be covered with the protective film PR as explained with reference to FIG. 11A before the etching of the second conductive layer 64 shown in FIG. 12C. This configuration can prevent the damage to the lower electrodes LE1, LE2 and LE3 by the etchant used at the time of the wet etching of the second conductive layer 64.

FIG. 14 is a cross-sectional view in which the display elements DE1 and DE2 shown in FIG. 13 are enlarged. In FIG. 14, the illustration of the lower side of the insulating layer 12, the resin layer 13, the sealing layer 14 and the resin layer 15 is omitted.

The display element DE1 comprises the lower electrode LE1 provided on the insulating layer 12, the organic layer OR1 provided on the lower electrode LE1 and including the light emitting layer EM1, and the upper electrode UE1 which is provided on the organic layer OR1 and which is in contact with the lower portion 61. In a manner similar to that of the display element DE1, the display element DE2 comprises the lower electrode LE2, the organic layer OR2 including the light emitting layer EM2, and the upper electrode UE2.

Each of the lower electrodes LE1 and LE2 is a multilayer body having an adhesive layer LEA formed of, for example, ITO, a reflective layer LEB formed of, for example, silver, and a transparent layer LEC formed of, for example, ITO.

Each of the organic layers OR1 and OR2 includes a plurality of functional layers such as a hole injection layer, a hole transport layer, an electron blocking layer, a hole blocking layer, an electron transport layer and an electron injection layer. Of these functional layers, at least the hole injection layer HIL is spaced apart from the first conductive layer 63. This configuration prevents undesired carrier leakage via the hole injection layer HIL.

The insulating layer 5 is provided on the insulating layer 12 and covers the peripheral portions of the lower electrodes LE1 and LE2. The insulating layer 5 is formed of, for example, an inorganic insulating material such as silicon oxide, silicon nitride or silicon oxynitride.

The partition 6 has the lower portion 61 provided on the insulating layer 5 and the upper portion 62 provided on the lower portion 61. The lower portion 61 has the first conductive layer 63 which covers the upper surface 5A of the insulating layer 5, and the second conductive layer 64 provided on the first conductive layer.

In the manufacturing method described above, each of the first conductive layer 63 and the insulating layer 5 is etched using the first resist R1 as a mask. Therefore, the width of the upper surface 5A and the width of the first conductive layer 63 are substantially equal to each other. Substantially the whole upper surface 5A is covered with the first conductive layer 63. The first conductive layer 63 is formed of, for example, a titanium-based material. The second conductive layer 64 is formed of, for example, an aluminum-based material.

The upper portion 62 has the first thin film 65 provided on the second conductive layer 64, and the second thin film 66 provided on the first thin film 65. The first conductive layer 63 and the upper portion 62 protrude from the side surfaces of the second conductive layer 64. The first thin film 65 is formed of, for example, a titanium-based material. The second thin film 66 is formed of, for example, an oxide conductive material.

The cap layer CP1 is provided on the upper electrode UE1. The sealing layer SE1 covers the cap layer CP1 and the partition 6. The cap layer CP2 is provided on the upper electrode UE2. The sealing layer SE2 covers the cap layer CP2 and the partition 6. Each of the sealing layers SE1 and SE2 is formed of, for example, an inorganic insulating material such as silicon oxide, silicon nitride or silicon oxynitride.

As explained above, the present embodiment can provide a display device and a manufacturing method thereof such that the reduction in reliability can be prevented.

All of the display devices and manufacturing methods thereof that can be implemented by a person of ordinary skill in the art through arbitrary design changes to the display device and manufacturing method thereof described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiment by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiment and are self-explanatory from the descriptions of the specification or can be arbitrarily conceived by a person of ordinary skill in the art are considered as the effects of the present invention as a matter of course.

Examples of a display device obtained from the configuration disclosed in this specification are additionally described below.

(1) A display device comprising:
a substrate;
a lower electrode provided above the substrate;
an inorganic insulating layer which covers a peripheral portion of the lower electrode;
a partition which has a lower portion provided on the inorganic insulating layer and an upper portion provided on the lower portion;
an organic layer provided on the lower electrode and including a light emitting layer; and
an upper electrode which is provided on the organic layer and is in contact with the lower portion, wherein
the lower portion has a first conductive layer which covers an upper surface of the inorganic insulating layer and a second conductive layer provided on the first conductive layer, and
the first conductive layer and the upper portion protrude from a side surface of the second conductive layer.

(2) The display device of (1), wherein
the organic layer includes a hole injection layer spaced apart from the first conductive layer.

(3) The display device of (1), further comprising:
a cap layer provided on the upper electrode; and
a sealing layer which is formed of an inorganic insulating material and covers the cap layer and the partition.

(4) The display device of (1), wherein
the first conductive layer is formed of a titanium-based material, and
the second conductive layer is formed of an aluminum-based material.

(5) The display device of (4), wherein
the upper portion has a first thin film provided on the second conductive layer and formed of a titanium-based material, and a second thin film provided on the first thin film.

(6) The display device of (1), wherein
the lower electrode has:
   a reflective layer formed of silver; and
   a transparent layer provided on the reflective layer.

(7) The display device of (1), wherein
the inorganic insulating layer is formed of silicon oxide, silicon nitride or silicon oxynitride.

What is claimed is:

1. A manufacturing method of a display device, comprising:
forming a lower electrode above a substrate;
forming an inorganic insulating layer which covers the lower electrode;
forming a lower portion layer and an upper portion layer on the inorganic insulating layer in series;
forming a patterned first resist on the upper portion layer;
removing the upper and lower portion layers exposed from the first resist in series by performing etching using the first resist as a mask;
forming a second resist which covers the lower portion layer and the upper portion layer and from which the inorganic insulating layer is exposed, after removing the first resist;
forming an aperture which overlaps the lower electrode in the inorganic insulating layer by performing etching using the second resist as a mask;
forming a partition which has a lower portion located on the inorganic insulating layer and an upper portion located on the lower portion and protruding from a side surface of the lower portion by applying etching to the lower portion layer, after removing the second resist; and
forming a stacked film including an organic layer and an upper electrode on the lower electrode in the aperture by performing vapor deposition using the partition as a mask.

2. The manufacturing method of claim 1, wherein
the forming the lower portion layer includes:
forming a first conductive layer on the inorganic insulating layer; and
forming a second conductive layer on the first conductive layer, and
the applying etching to the lower portion layer includes
retracting the second conductive layer from an end portion of each of the first conductive layer and the upper portion layer.

3. The manufacturing method of claim 2, wherein
the second conductive layer is formed of an aluminum-based material.

4. The manufacturing method of claim 3, wherein
the first conductive layer is formed of a titanium-based material.

5. The manufacturing method of claim 4, wherein
the forming the upper portion layer includes:
forming a first thin film on the second conductive layer; and
forming a second thin film on the first thin film, and
the first thin film is formed of a titanium-based material.

6. The manufacturing method of claim 1, wherein
the forming the lower electrode includes:
forming an adhesive layer on an insulating layer;
forming a reflective layer on the adhesive layer; and
forming a transparent layer on the reflective layer.

7. The manufacturing method of claim 6, wherein
the reflective layer is formed of silver.

8. The manufacturing method of claim 6, further comprising:
forming a protective film which covers the aperture, after forming the aperture; and
removing the protective film, after applying etching to the lower portion layer.

9. The manufacturing method of claim 1, further comprising, after forming the stacked film,
forming a sealing layer which covers the stacked film and the partition by using an inorganic insulating material.

10. The manufacturing method of claim 9, further comprising, after forming the sealing layer,
forming a patterned third resist on the sealing layer, and
removing the sealing layer and the stacked film exposed from the third resist in series by performing etching using the third resist as a mask.

11. A manufacturing method of a display device, comprising:
forming a lower electrode above a substrate;
forming an inorganic insulating layer which covers the lower electrode;
forming a lower portion layer and an upper portion layer on the inorganic insulating layer in series;
forming a patterned first resist on the upper portion layer;
forming an aperture which overlaps the lower electrode in the inorganic insulating layer by performing etching using the first resist as a mask such that the upper portion layer, the lower portion layer and the inorganic insulating layer exposed from the first resist are removed in series;
forming a partition which has a lower portion located on the inorganic insulating layer and an upper portion located on the lower portion and protruding from a side surface of the lower portion by applying etching to the lower portion layer, after removing the first resist; and
forming a stacked film including an organic layer and an upper electrode on the lower electrode in the aperture by performing vapor deposition using the partition as a mask.

12. The manufacturing method of claim 11, wherein
the forming the lower portion layer includes:
forming a first conductive layer on the inorganic insulating layer; and
forming a second conductive layer on the first conductive layer, and
the applying etching to the lower portion layer includes
retracting the second conductive layer from an end portion of each of the first conductive layer and the upper portion layer.

13. The manufacturing method of claim 12, wherein
the second conductive layer is formed of an aluminum-based material.

14. The manufacturing method of claim 13, wherein
the first conductive layer is formed of a titanium-based material.

15. The manufacturing method of claim 14, wherein
the forming the upper portion layer includes:
forming a first thin film on the second conductive layer; and
forming a second thin film on the first thin film, and
the first thin film is formed of a titanium-based material.

16. The manufacturing method of claim 11, wherein
the forming the lower electrode includes:
forming an adhesive layer on an insulating layer;
forming a reflective layer on the adhesive layer; and
forming a transparent layer on the reflective layer.

17. The manufacturing method of claim 16, wherein
the reflective layer is formed of silver.

18. The manufacturing method of claim 16, further comprising:
forming a protective film which covers the aperture, after forming the aperture; and
removing the protective film, after applying etching to the lower portion layer.

19. The manufacturing method of claim 11, further comprising, after forming the stacked film,
forming a sealing layer which covers the stacked film and the partition by using an inorganic insulating material.

20. The manufacturing method of claim 19, further comprising, after forming the sealing layer,
forming a patterned third resist on the sealing layer, and
removing the sealing layer and the stacked film exposed from the third resist in series by performing etching using the third resist as a mask.
